(19) United States
(12) Patent Application Publication
(10) Pub. No.: US 2026/0370170 A1
(43) Pub. Date: Nov. 19, 2026

(54) LINEAR MOTOR WITH COGGING COMPENSATION

(71) Applicant: ASML Netherlands B.V., Veldhoven (NL)

(72) Inventors: Hansol MOON, Norwalk, CT (US); Rokesh GAJAPATHY, Venlo (NL); John Wesley ROBINSON, Bethel, CT (US); Nathan Robert FINNEY, Trumbull, CT (US); Stephen ROUX, New Fairfield, CT (US); Arjun VERMA, Danbury, CT (US)

(73) Assignee: ASML Netherlands B.V., Veldhoven (NL)

(21) Appl. No.: 19/515,859

(22) PCT Filed: Aug. 2, 2024
(86) PCT No.: PCT/EP2024/072019

§ 371 Date: Mar. 3, 2026

Related U.S. Application Data
(60) Provisional application No. 63/536,794, filed on Sep. 6, 2023.

(51) Int. Cl. H02P 25/064; G03F 7/00; H02K 41/03

(52) U.S. Cl. CPC H02P 25/064; G03F 7/70716; G03F 7/70758; G03F 7/7085; G03F 7/70991; H02K 41/031

(57) ABSTRACT

An actuator system includes a linear motor that has a first part, the first part being electrically communicable with a multi-phase power source and comprising an array of coils, the coils each having a respective ferromagnetic core, a second part, the second part comprising an array of magnets, the first and second parts being movable relative to each other in response to electrical signals from the multi-phase power source, a force sensor, configured to measure a force of mutual attraction between the first part and the second part, and a controller, configured to control the electrical signals responsive to variations in the force of mutual attraction.

### CROSS-REFERENCE TO RELATED APPLICATIONS

This application claims priority of U.S. application 63/536,794 which was filed on 6 Sep. 2023, and which is incorporated herein in its entirety by reference.

### FIELD

The present description relates to methods and apparatus for high resolution control of linear motors, and more particularly to the use and control of such motors in electromechanical systems for lithography.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., including part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti parallel to this direction. It is also possible to transfer the pattern from the patterning device to the substrate by imprinting the pattern onto the substrate.

### SUMMARY

A linear motor has a first part, the first part being electrically communicable with a multi-phase power source and comprising an array of coils, the coils each having a respective ferromagnetic core, a second part, the second part comprising an array of magnets, the first and second parts being movable relative to each other in response to electrical signals from the multi-phase power source, a force sensor, configured and arranged to measure a force of mutual attraction between the first part and the second part, and a controller, configured and arranged to control the electrical signals responsive to variations in the force of mutual attraction.

In an aspect, there is provided a method of manufacturing devices wherein a device pattern is applied to a series of substrates using a lithographic process, the method including controlling the motion of a patterning device support using a method described herein and exposing the device pattern onto the substrates.

In aspect, there is provided a non-transitory computer program product comprising machine-readable instructions configured to cause a processor to cause performance of a method described herein.

### BRIEF DESCRIPTION OF THE DRAWINGS

Embodiments will now be described, by way of example only, with reference to the accompanying drawings in which:

FIG. 1 schematically depicts an embodiment of a lithographic apparatus;

FIG. 2 schematically depicts an embodiment of a lithographic cell or cluster;

FIG. 3 schematically illustrates a linear motor;

FIG. 4 schematically illustrates a control system for a linear motor incorporating force sensors in accordance with an embodiment;

FIG. 5 schematically illustrates an arrangement of force sensors;

FIG. 6 schematically illustrates an alternate force sensor arrangement;

FIG. 7 schematically illustrates an arrangement of acceleration sensors;

FIG. 8 schematically illustrates an alternate arrangement of acceleration sensors;

FIG. 9 schematically illustrates an additional alternate arrangement of acceleration sensors; and

FIG. 10 schematically illustrates an additional alternate arrangement of acceleration sensors.

### DETAILED DESCRIPTION

Before describing embodiments in detail, it is instructive to present an example environment in which embodiments may be implemented.

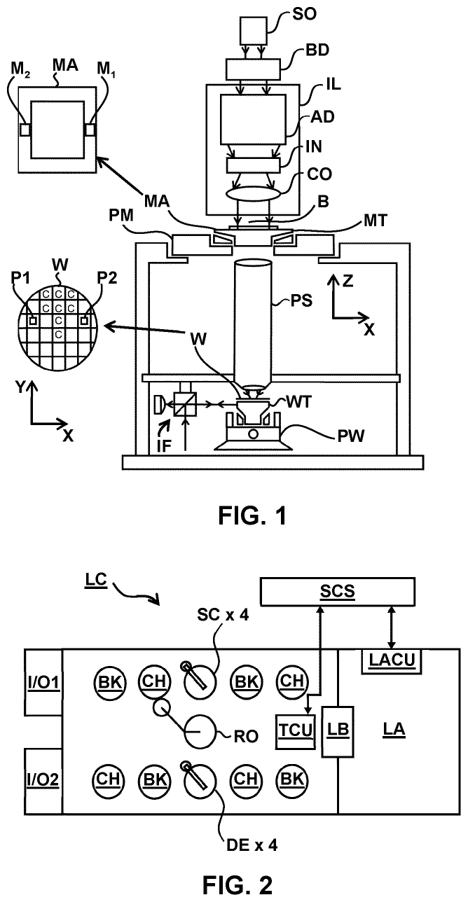

FIG. 1 schematically depicts a lithographic apparatus LA. The apparatus comprises:
an illumination system (illuminator) IL configured to condition a radiation beam B (e.g. DUV radiation or EUV radiation);
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WTa constructed to hold a substrate (e.g. a resist-coated wafer) W and connected to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The patterning device support structure holds the patterning device in a manner that depends on the orientation of the patterning device, the design of the lithographic apparatus, and other conditions, such as for example whether or not the patterning device is held in a vacuum environment. The patterning device support structure can use mechanical, vacuum, electrostatic or other clamping techniques to hold the patterning device. The patterning device support structure may be a frame or a table, for example, which may be fixed or movable as required. The patterning device support structure may ensure that the patterning device is at a desired position, for example with respect to the projection system. Any use of the terms “reticle” or “mask” herein may be considered synonymous with the more general term “patterning device”.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more tables (e.g., two or more substrate table, two or more patterning device support structures, or a substrate table and metrology table). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross section.

The radiation beam B is incident on the patterning device (e.g., mask) MA, which is held on the patterning device support (e.g., mask table MT), and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table WTa can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan. In general, movement of the patterning device support (e.g., mask table) MT may be realized with the aid of a long-stroke module (coarse positioning) and a short-stroke module (fine positioning), which form part of the first positioner PM. Similarly, movement of the substrate table WTa may be realized using a long-stroke module and a short-stroke module, which form part of the second positioner PW. In the case of a stepper (as opposed to a scanner) the patterning device support (e.g., mask table) MT may be connected to a short-stroke actuator only, or may be fixed.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment markers may also be included within dies, in amongst the device features, in which case it is desirable that the markers be as small as possible and not require any different imaging or process conditions than adjacent features. The alignment system, which detects the alignment markers is described further below.

The depicted apparatus could be used in at least one of the following modes:
In step mode, the patterning device support (e.g., mask table) MT and the substrate table WTa are kept essentially stationary, while an entire pattern imparted to the radiation beam is projected onto a target portion C at one time (i.e., a single static exposure). The substrate table WTa is then shifted in the X and/or Y direction so that a different target portion C can be exposed. In step mode, the maximum size of the exposure field limits the size of the target portion C imaged in a single static exposure.
In scan mode, the patterning device support (e.g., mask table) MT and the substrate table WTa are scanned synchronously while a pattern imparted to the radiation beam is projected onto a target portion C (i.e., a single dynamic exposure). The velocity and direction of the substrate table WTa relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
In another mode, the patterning device support (e.g., mask table) MT is kept essentially stationary holding a programmable patterning device, and the substrate table WTa is moved or scanned while a pattern imparted to the radiation beam is projected onto a target portion C. In this mode, generally a pulsed radiation source is employed and the programmable patterning device is updated as required after each movement of the substrate table WTa or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

Lithographic apparatus LA is of a so-called dual stage type which has two tables WTa, WTb (e.g., two substrate tables) and two stations—an exposure station and a measurement station—between which the tables can be exchanged. For example, while a substrate on one table is being exposed at the exposure station, another substrate can be loaded onto the other substrate table at the measurement station and various preparatory steps carried out. The preparatory steps may include mapping the surface control of the substrate using a level sensor LS and measuring the position of alignment markers on the substrate using an alignment sensor AS, both sensors being supported by a reference frame RF. If the position sensor IF is not capable of measuring the position of a table while it is at the measurement station as well as at the exposure station, a second position sensor may be provided to enable the positions of the table to be tracked at both stations. As another example, while a substrate on one table is being exposed at the exposure station, another table without a substrate waits at the measurement station (where optionally measurement activity may occur). This other table has one or more measurement devices and may optionally have other tools (e.g., cleaning apparatus). When the substrate has completed exposure, the table without a substrate moves to the exposure station to perform, e.g., measurements and the table with the substrate moves to a location (e.g., the measurement station) where the substrate is unloaded and another substrate is load. These multi-table arrangements enable a substantial increase in the throughput of the apparatus.

As shown in FIG. 2, the lithographic apparatus LA may form part of a lithographic cell LC, also sometimes referred to as a lithocell or lithocluster, which also includes apparatus to perform one or more pre- and post-exposure processes on a substrate. Conventionally these include one or more spin coaters SC to deposit a resist layer, one or more developers DE to develop exposed resist, one or more chill plates CH and one or more bake plates BK. A substrate handler, or robot, RO picks up a substrate from input/output ports I/O1, I/O2, moves it between the different process devices and delivers it to the loading bay LB of the lithographic apparatus. These devices, which are often collectively referred to as the track, are under the control of a track control unit TCU which is itself controlled by the supervisory control system SCS, which also controls the lithographic apparatus via lithographic control unit LACU. Thus, the different apparatus may be operated to maximize throughput and processing efficiency.

In order that the substrate that is exposed by the lithographic apparatus is exposed correctly and consistently, it is desirable to inspect an exposed substrate to measure one or more properties such as overlay error between subsequent layers, line thickness, critical dimension (CD), etc. If an error is detected, an adjustment may be made to an exposure of one or more subsequent substrates. This may particularly useful, for example, if the inspection can be done soon and fast enough that another substrate of the same batch is still to be exposed. Also, an already exposed substrate may be stripped and reworked (to improve yield) or discarded, thereby avoiding performing an exposure on a substrate that is known to be faulty. In a case where only some target portions of a substrate are faulty, a further exposure may be performed only on those target portions which are good. Another possibility is to adapt a setting of a subsequent process step to compensate for the error, e.g. the time of a trim etch step can be adjusted to compensate for substrate-to-substrate CD variation resulting from the lithographic process step.

An inspection apparatus is used to determine one or more properties of a substrate, and in particular, how one or more properties of different substrates or different layers of the same substrate vary from layer to layer and/or across a substrate. The inspection apparatus may be integrated into the lithographic apparatus LA or the lithocell LC or may be a stand-alone device. To enable most rapid measurements, it is desirable that the inspection apparatus measure one or more properties in the exposed resist layer immediately after the exposure. However, the latent image in the resist has a very low contrast—there is only a very small difference in refractive index between the part of the resist which has been exposed to radiation and that which has not—and not all inspection apparatus have sufficient sensitivity to make useful measurements of the latent image. Therefore measurements may be taken after the post-exposure bake step (PEB) which is customarily the first step carried out on an exposed substrate and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibility for rework of a faulty substrate but may still provide useful information, e.g. for the purpose of process control.

In general, the long-stroke module of the mask table MT requires a combination of high speed movement, high acceleration, and precise positioning (although less precise than that provided by the corresponding short-stroke module). For example, such a long-stroke module may have acceleration greater than 900 m/s², for example 960 m/s², or higher. Furthermore, it may move at a velocity of greater than 8 m/s during its movements. As will be appreciated, the high acceleration allows the stage to reach its desired velocity over a very short time and distance, which in turn allows the table to move smoothly through the illumination area during exposure.

The long stroke module uses a number of actuators that each can generate a force in horizontal either X or Y) and vertical direction (Z). Each of the actuators has one or more commutators that are used to control the motor by way of setpoint values which may include current, voltage, and/or phase for each of three phases of motor current. The position of the coils relative to the magnets is measured using a position sensor (relative or absolute). An example of a multi-phase linear motor of this type is described in U.S. Pat. No. 7,061,587, incorporated herein by reference in its entirety.

In general, there is a delay in the process from position acquisition to actuation because the position sensor part of the position control loop (outer-loop) is orders of magnitude slower than the current control loop (inner-loop) which is responsible for actuation. Part of that delay may be compensated in the sensor interface, and part may be handled in the motor interface block. The delay generally has a significant effect on the fast changing horizontal position (X and Y) that is used to calculate the commutation angle. This can be compensated by using a delay compensation block at the sensor and actuator level, which can be represented by Eqn. 1.

$${delay}_{comp} = ( 1 + \frac{{xtrlpol}_{delay} \cdot s}{\frac{1}{{( 2 π \cdot {f}_{lp} )}^{2}} {s}^{2} + \frac{2 β}{2 π \cdot {f}_{lp}} + 1} ) \cdot pos \qquad Eqn . ( 1 )$$

Wherein xtrpol_{delay} [s] is the to be compensated delay, fₗₚ [Hz] is the cutoff frequency of a low pass filter, β is the damping for the low pass filter, pos [m] is the sensor position, and delay_{comp} [m] is the delay compensated position.

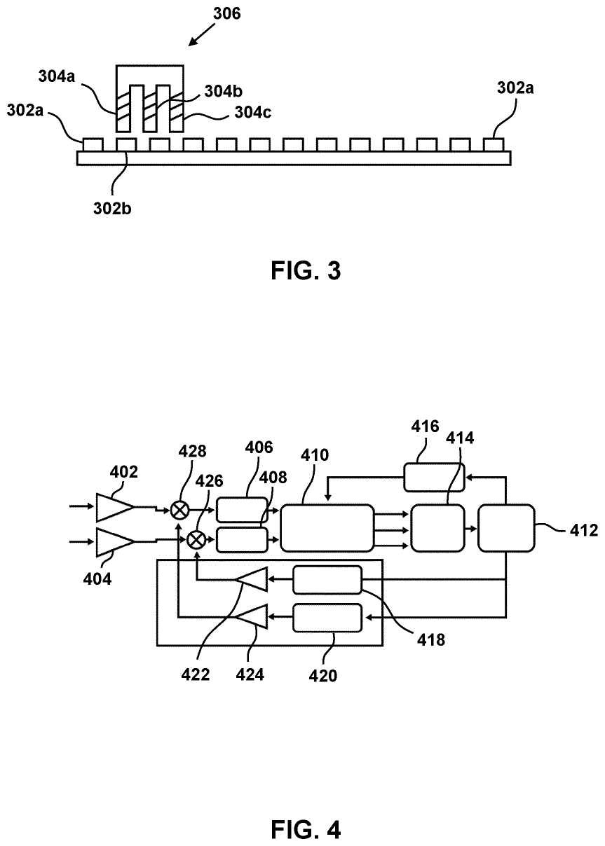

As shown schematically in FIG. 3, linear motors as used in lithographic systems may have two double-sided linear motors in parallel. These motors are constructed as a long row of magnets 302a, b . . . , n mounted parallel to one another, and a cooperating set of three coils 304a-c mounted in a coil block generally indicated at 306. Where the coils are wound around a ferromagnetic coil, these linear motors are referred to as slotted iron-core Linear-Permanent Magnet Synchronous Machines (L-PMSMs), which are also known as IC LiMMS motors (Linear Motor Motion Systems). The coil block 306 can be mounted on the balance mass (BM) side of the system, and magnets mounted on the long stroke side of the system, or vice-versa. That is, either the magnets or the coils can constitute the stator or stationary part of the magnet system while the other constitutes the moving part.

As can be seen from FIG. 3, there are positions at which the coils 304a-c are more aligned with the magnets 302a . . . n or at which they are more aligned with gaps between the magnets. Due to this varying spatial relationship between magnets and coils, the interaction of the magnetic and electric fields between the magnets and coil cores results in preferred positions of the motor. A larger force is necessary to move the motors away from these positions. This effect is called cogging. Though the use of iron core linear motors creates cogging problems, the advantages of this type of motor such as improved efficiency and higher force density limits may make them useful in advanced EUV systems having high demands on long-stroke actuator performance.

One approach to solving the cogging issue has been to apply corrections to the motor control loop using estimated acceleration based on position readings for the long-stroke motor. When the second derivative of position is used as a feed forward input in this manner, it has shown some success at correcting a portion of the disturbance due to cogging.

In a conventional linear permanent magnet synchronous motor, L-PMSM, the inductance of the coils in both the thrust and stator axis directions are generally equal, or can be assumed to be for the purpose of determining a quadrature current. The quadrature current then is directly proportionate to the thrust as in Eqn. 2.

$${F}_{y} = \frac{3}{2} \frac{π}{τ} [ Ψ + ( {L}_{d} - {L}_{q} ) {i}_{d} ] {i}_{q} \qquad Eqn . ( 2 )$$

Control using Direct Quadrature Zero Transform techniques has been implemented, however such an approach requires sampling phase currents from the power amplifier and transforming them into direct stator and quadrature currents to control the motor thrust. The inventors have found that thrust estimated using this approach fails to account for some of the issues, including cogging.

However, by applying a fast sampling sensor that can detect acceleration of the moving portion of the linear motor, the resulting sensor output may be amplified (multiplied by a gain function) and passed to a controller. Controller output is then transformed into RST phase information as shown in FIG. 4.

The setpoint information (Fz, Fy) is passed through respective amplifiers 402, 404 each having a gain of, for example, 1/g, and passed to respective proportional integral controllers (PI) 406, 408. The signals from the PI controllers are passed to the inverse DQZ transform 410, and the RST current information is sent to the linear motor 412 via an inverter 414. The inverse DQZ transform 410 may also have input from encoder 416 which provides position information.

The linear motor 412 is monitored by a y force sensor 418 and a z force sensor 420, each of which have corresponding amplifiers 422, 424. The amplified output of the force sensors is combined at combiner 426 and 428 respectively prior to the PI controllers. The load cell gain can be determined by way of look-up tables generated with simulations, or may be calculated analytically.

Using this approach allows for fast computation by reducing complexity of the necessary transforms and reducing the need for cogging feedforward calculated values.

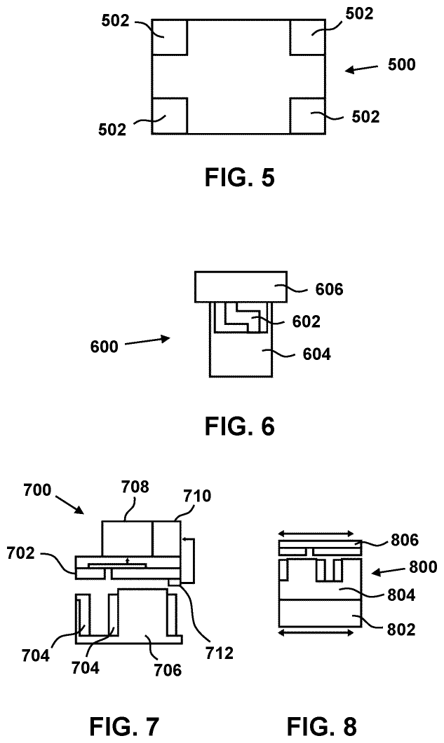

A variety of force sensing arrangements may be employed. In an embodiment, a number of load sensors can be incorporated into the structure of one or more teeth of the coil side. An example is schematically illustrated in FIG. 5.

One or each tooth 500 may include four force sensors 502, for example at each corner of the tooth. The force sensors 502 can each be, for example, a three axis piezoelectric load sensor, which together provide Fx, Fy, Fz, Rz, Ry, and Rx per tooth.

In an embodiment, one or each tooth 600 may include a strain gage (load cell) 602, interposed between the tooth 604 and the base 606.

In an embodiment, flux sensors such as Hall sensors may be placed into the airgaps between coils.

An embodiment may include the use of accelerometers either mounted in the magnet side as in FIG. 7 or on the coil side as in FIG. 8.

In the embodiment illustrated in FIG. 7, the magnet side 700 includes an accelerometer 702 mounted thereto. The coils 704 are illustrated schematically as wound around respective cores, 706. Such an accelerometer may transmit its output signal wirelessly by way of a wireless transmitter 708, which finds particular utility in the case where the magnet side constitutes the movable part of the linear motor.

In an embodiment, the wireless transmitter 708 is selected to have low power requirements, and may be powered by a battery 710. The battery 710 may in turn be rechargeable by way of, for example, a charging coil 712 which is passive, generating charging current due to the relative motion between the magnet side and the coils.

In the embodiment of FIG. 8, the array of teeth 800 is mounted on the balance mass 802, and an accelerometer 804 is located on the tooth side. The magnet side is shown at 806. In this arrangement, either side may be the movable part or the stationary part, as illustrated by the arrows.

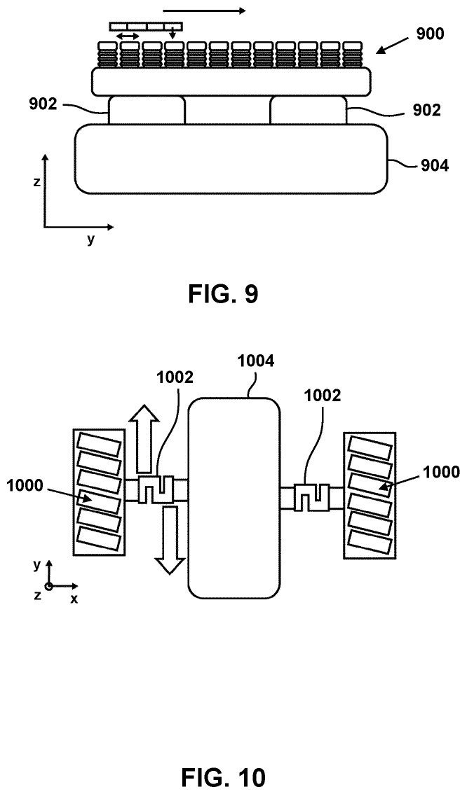

In the embodiment illustrated in FIG. 9, the load cells 902 are positioned between the array of teeth 900 and the balance mass 904. In the embodiment illustrated in FIG. 10, the magnet arrays 1000 act as the long stroke motors carrying a stage 1004 that may itself include a carrier, chuck, and short stroke module, for example. The load cells 1002 are interposed between the stage and the long stroke motors.

As will be appreciated, in either configuration, the output of the accelerometer may be converted to force information by way of the well-known relationship, F=ma.

While this disclosure has been concerned primarily with the mask table MT, of a lithographic apparatus, it will be appreciated that any linear motor for which high speeds, high accelerations, and high precision are important, the same control approach can be applied to reduce effects of cogging. For example, the wafer stages WTa, WTb could include such motors in their respective long-stroke modules. Because of the demagnification between the mask and wafer in a typical lithographic system, the requirements for speed at the wafer level are not as demanding as at the mask level. However, future developments may lead to higher throughput systems in which the wafer table would benefit from application of the systems and methods described herein.

In some cases such tools may include auxiliary stages. That is, stages that are configured to convey supply lines including, for example, electrical supply lines, or fluid (i.e., liquids or gases) supply lines. By including a separately controlled stage for these lines, the lines can be made to exert little or no force on the main stages to which they are auxiliary.

Likewise, while the context of the systems and methods described herein has been photolithography, other high precision, high speed tools may make use of similar approaches, including, but not limited to inspection tools, e-beam stages, and other types of tools altogether outside the realm of integrated circuit manufacturing.

Various embodiments of the present systems and methods are disclosed in the subsequent list of numbered clauses:
1. A linear motor comprising:
   a first part, the first part being electrically communicable with a multi-phase power source and comprising an array of coils, the coils each having a respective ferromagnetic core;
   a second part, the second part comprising an array of magnets, the first and second parts being movable relative to each other in response to electrical signals from the multi-phase power source;
   a force sensor, configured to measure a force of mutual attraction between the first part and the second part; and
   a controller, configured to control the electrical signals responsive to variations in the force of mutual attraction.
2. A linear motor as in clause 1, wherein the controller, force sensor, and multi-phase power source are arranged in a feedback control loop.
3. A linear motor as in clause 1, wherein the controller, force sensor, and multi-phase power source are arranged in a feedforward control loop.
4. A linear motor as in any of clauses 1-3 wherein the force sensor is selected from the group consisting of a load cell, a piezoelectric load sensor, a flux sensor, and an accelerometer configured to convert acceleration data into force data.
5. A linear motor as in any of clauses 1-4, wherein the first part is a movable part and the second part is a stationary part.
6. A linear motor as in any of clauses 1-4, wherein the first part is a stationary part and the second part is a movable part.
7. A stage system in an inspection tool comprising a linear motor as in any of clauses 1-6.
8. A stage system of a photolithography tool comprising a linear motor as in any of clauses 1-6.
9. A stage system as in clauses 7 or 8, in which the linear motor is configured as a long stroke motor of the stage system.
10. A stage system as in clauses 7 or 8, wherein the stage system comprises a wafer stage.
11. A stage system as in clauses 7 or 8, wherein the stage system comprises a reticle stage.
12. A stage system as in clauses 7 or 8, wherein the stage system comprises an auxiliary stage carrying at least one of: electrical supply lines and fluid supply lines.
13. A stage system as in any of clauses 7-12, wherein the force sensor is positioned between a long stroke module of the stage system and a short stroke module of the stage system.
14. A stage system as in any of clauses 7-12, wherein the force sensor is positioned between a balance mass of the stage system and the first and second parts.
15. A stage system as in any of clauses 7-14 wherein each ferromagnetic core comprises an iron core.
16. A linear motor as in any of clauses 1-6, wherein each ferromagnetic core comprises an iron core.

The terms “optimize”, “optimizing” and “optimization” as used herein mean adjusting a lithographic process parameter such that results and/or processes of lithography have a more desirable characteristic, such as higher accuracy of projection of a design layout on a substrate, a larger process window, etc.

An embodiment of the invention may take the form of a computer program containing one or more sequences of machine-readable instructions describing a method as disclosed herein, or a data storage medium (e.g. semiconductor memory, magnetic or optical disk) having such a computer program stored therein. Further, the machine readable instruction may be embodied in two or more computer programs. The two or more computer programs may be stored on one or more different memories and/or data storage media.

This computer program may be included, for example, with or within the imaging apparatus of FIG. 1 and/or with or within the control unit LACU of FIG. 2. Where an existing apparatus, for example of the type shown in FIGS. 1 and 2, is already in production and/or in use, an embodiment can be implemented by the provision of updated computer program products for causing a processor of the apparatus to perform a method as described herein.

Any controllers described herein may each or in combination be operable when the one or more computer programs are read by one or more computer processors located within at least one component of the lithographic apparatus. The controllers may each or in combination have any suitable configuration for receiving, processing, and sending signals. One or more processors are configured to communicate with the at least one of the controllers. For example, each controller may include one or more processors for executing the computer programs that include machine-readable instructions for the methods described above. The controllers may include data storage medium for storing such computer programs, and/or hardware to receive such medium. So the controller(s) may operate according the machine readable instructions of one or more computer programs.

Although specific reference may have been made above to the use of embodiments in the context of lithography using radiation, it will be appreciated that an embodiment of the invention may be used in other applications, for example imprint lithography, and where the context allows, is not limited to lithography using radiation. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

Further, although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The patterning device described herein may be referred to as a lithographic patterning device. Thus, the term “lithographic patterning device” may be interpreted as meaning a patterning device which is suitable for use in a lithographic apparatus.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The embodiment(s) described, and references in the specification to an “embodiment”, “example,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

The descriptions above are intended to be illustrative, not limiting. Thus, it will be apparent to one skilled in the art that modifications may be made to the invention as described without departing from the scope of the claims set out below. For example, one or more aspects of one or more embodiments may be combined with or substituted for one or more aspects of one or more other embodiments as appropriate. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance. The breadth and scope of the invention should not be limited by any of the above-described exemplary embodiments, but should be defined only in accordance with the following claims and their equivalents.

1. A linear motor comprising:
a first part, the first part being electrically communicable with a multi-phase power source and comprising an array of coils, the coils each having a respective ferromagnetic core;
a second part, the second part comprising an array of magnets, the first and second parts being movable relative to each other in response to electrical signals from the multi-phase power source;
a force sensor, configured to measure a force of mutual attraction between the first part and the second part; and
a controller, configured to control the electrical signals responsive to variations in the force of mutual attraction.

2. The linear motor of claim 1, wherein the controller, force sensor, and multi-phase power source are arranged in a feedback control loop.

3. The linear motor of claim 1, wherein the controller, force sensor, and multi-phase power source are arranged in a feedforward control loop.

4. The linear motor of claim 1 wherein the force sensor is selected from the group consisting of a load cell, a piezoelectric load sensor, a flux sensor, and an accelerometer configured to convert acceleration data into force data.

5. The linear motor of claim 1, wherein the first part is a movable part and the second part is a stationary part.

6. The linear motor of claim 1, wherein the first part is a stationary part and the second part is a movable part.

7. A stage system comprising the linear motor of claim 1.

8. The stage system of claim 7, wherein the stage system is part of a photolithography tool.

9. The stage system of claim 7, wherein the linear motor is configured as a long stroke motor of the stage system.

10. The stage system of claim 7, wherein the stage system comprises a wafer stage or a reticle stage.

11. The stage system of claim 7, wherein the stage system comprises an auxiliary stage carrying at least one of: electrical supply lines and fluid supply lines.

12. The stage system of claim 7, wherein the force sensor is positioned between a long stroke module of the stage system and a short stroke module of the stage system.

13. The stage system of claim 7, wherein the force sensor is positioned between a balance mass of the stage system and the first and second parts.

14. The stage system of claim 7, wherein each ferromagnetic core comprises an iron core.

15. The linear motor of claim 1, wherein each ferromagnetic core comprises an iron core.

16. The stage system of claim 7, wherein the stage system is in an inspection tool.
